(19) United States
(12) Patent Application Publication
(10) Pub. No.: US 2003/0111618 A1
(43) Pub. Date: Jun. 19, 2003

(54) Methods and devices for detecting a distribution of charged-particle density of a charged-particle beam in charged-particle-beam microlithography systems

(75) Inventors: Jin Udagawa, Fukaya-shi (JP); Noriyuki Hirayanagi, Tokyo (JP)

Correspondence Address: KLARQUIST SPARKMAN, LLP, One World Trade Center, Suite 1600, 121 S. W. Salmon Street, Portland, OR, 97204, US

(73) Assignee: Nikon Corporation

(21) Appl. No.: 10/264,093

(22) Filed: Oct. 2, 2002

(30) Foreign Application Priority Data
Oct. 2, 2001 (JP) 2001-306668

(51) Int. Cl. H01J 37/302

(52) U.S. Cl. 250/492.22; 250/397

(57) ABSTRACT

Charged-particle-beam (CPB) microlithography systems are disclosed that include a device for measuring the distribution of charged-particle density in a patterned beam. By providing feedback to the CPB microlithography apparatus, the distribution of charged-particle density can be optimized for high-quality exposures. An embodiment of the device includes a pinhole diaphragm defining an aperture having a small cross-dimension compared to the transverse width of the patterned beam produced by the system. The device also desirably includes a downstream scattering-contrast diaphragm defining an aperture having a larger cross dimension than that of the pinhole aperture. A photodiode or the like is downstream of the pinhole aperture and is used for detecting charged particles transmitted by the pinhole diaphragm. A patterned beam is scanned across the pinhole aperture, and charged particles not scattered during passage through the pinhole aperture propagate to the photodiode. The distribution of charged particle density is obtained from the photodiode signal, which can be fed back to components of the CPB microlithography system.

### FIELD

This disclosure pertains to microlithography, particularly microlithography in which the lithographic energy beam is a charged particle beam. Microlithography is a key technology used in the fabrication of microelectronic devices such as semiconductor integrated circuits, displays, and the like. More specifically, the disclosure pertains to methods and devices, used in connection with charged-particle-beam microlithography, for detecting and optimizing the distribution of charged-particle density in a “patterned beam” as incident on the lithographic substrate.

### BACKGROUND

In recent years, as the linewidth of circuit elements in microelectronic devices has continued to decrease, the pattern-resolution limitations of optical microlithography have become increasingly difficult to accommodate. As a result, large research and development efforts have been underway to develop a practical “next generation” lithography (NGL) technology. One NGL approach is microlithography performed using a charged particle beam such as an electron beam or ion beam.

Part of the development of a practical charged-particle-beam (CPB) microlithography system has been directed to obtaining a suitably high throughput. The conventional type of CPB microlithography involves direct writing of a pattern line by line on the lithographic substrate. Unfortunately, this technique has a throughput that is too low for practical use in large-scale wafer-fabrication processes (and thus is used mainly for reticle production). Another technique that has received attention is one-shot full-reticle exposure, similar to the manner of exposing a full reticle in optical microlithography. Unfortunately, this technique has defied practical application because of the impossibility of fabricating a single-shot reticle and of fabricating CPB lenses capable of projecting large-field images without producing unacceptably high off-axis aberrations. A compromise technique is the “divided reticle” technique in which the pattern as defined on the reticle is divided into multiple regions, termed “subfields,” that define respective portions of the pattern. The subfields are exposed individually, and the respective images of the subfields are formed on the lithographic substrate such that the images are “stitched” together to form the complete transferred pattern.

Divided-reticle microlithography exhibits a throughput that is intermediate the direct-writing technique and the one-shot full-reticle exposure technique. Hence, current development effort is directed to obtaining ever-increasing throughput from the divided-reticle technique. One way in which to obtain greater throughput is to increase the area of the reticle (which defines the pattern to be transferred to the lithographic substrate) illuminated by the charged-particle illumination beam per exposure shot.

A typical area of the reticle illuminated by the illumination beam per shot is approximately 1-mm square. The distribution of charged-particle density within the illuminated region is affected by the performance of the charged-particle source and on the “illumination-optical system” (the system of lenses and deflectors, situated upstream of the reticle, that directs the illumination beam from the source to the selected illumination region on the reticle). If the distribution of charged-particle density (i.e., the density profile of charged particles in the transverse dimension of the beam) within the illumination beam is not uniform, then the exposed pattern is not uniform. Hence, it is desirable that the density distribution of the illumination beam be as uniform as possible.

One conventional method for measuring the distribution of charged-particle density involves scanning the charged particle beam across an aperture having a diameter that is smaller than the transverse diameter of the beam (or scanning a stage, on which the aperture is located, across the beam). The charged particles passing through the aperture are detected using a Faraday cup. Unfortunately, in this method, the particle-detection signal produced by the Faraday cup is an electrical-current signal that is amplified. Experience has shown that this amplified signal has a signal-to-noise (S/N) ratio that is too low for practical use.

Another conventional method for measuring the distribution of charged-particle density of the beam involves using a photoconversion element such as a scintillator, which produces light photons from incident charged particles. In order to obtain the sufficiently high S/N ratio for measuring the small amount of light produced by the photoconversion element of the scintillator, a photodetector such as a photomultiplier tube must be used. Unfortunately, scintillators and photomultiplier tubes are bulky and complex, and are difficult to impossible to accommodate in the extremely limited space inside the CPB microlithography system. Also, these components require high-voltage wiring, which can cause problems with stray fields inside the CPB microlithography system.

### SUMMARY

In view of the shortcomings of conventional devices and methods as summarized above, the present invention provides, inter alia, charged-particle-beam (CPB) microlithography apparatus capable of producing measurements of the distribution of charged-particle density, of the illumination beam, having a substantially higher signal-to-noise (S/N) ratio. The signal can be used in a feedback scheme by which optical components in the CPB source, illumination-optical system, and projection-optical system are controlled so as to obtain a highly accurate exposure.

A first aspect of the invention is set forth in the context of a CPB microlithography system for exposing a pattern, defined on a segmented reticle, onto a sensitive substrate. More specifically, the first aspect of the invention is directed to devices for measuring a lateral distribution, produced by the system, of charged-particle density of the exposed pattern on a substrate plane. The “pattern” for measurement purposes can be a full-open pattern. An embodiment of such a device comprises a pinhole diaphragm, defining a pinhole aperture, situated on an image plane of the CPB microlithography system. The pinhole aperture has a cross-dimension and is situated such that at least a portion of a patterned beam, propagating downstream of a reticle plane of the CPB microlithography system, can pass through the pinhole aperture.

The device also includes a semiconductor amplifying CPB detector (e.g., a PIN photodiode) situated downstream of the pinhole aperture. The CPB detector is configured to receive the portion of the patterned beam passing through the pinhole aperture and that is incident on the CPB detector. The CPB detector detects the incident charged particles and produces an amplified output current from the detected incident charged particles. The amplification is due to the generation of multiple electron-hole pairs by a single incident charged particle. The semiconductor amplifying CPB detector allows, within the extremely tight spatial constraints inside a CPB microlithography system, the distribution of charged particle density in the beam to be determined at a sufficiently high signal-to-noise (S/N) ratio. Moreover, in contrast with scintillators and photomultipliers, semiconductor amplifying CPB detectors dispense with the need to provide high-voltage wiring; only low-voltage wiring for conducting detected signals is required.

By measuring the electric current of the charged particle beam that has passed through the pinhole aperture, the distribution of the density of charged particles in the beam is readily determined at a high signal-to-noise (S/N) ratio. This, in turn, allows the uniformity of illumination intensity of the beam to be optimized for the prevailing exposure conditions.

The device further can comprise a scattering-contrast diaphragm situated downstream of the pinhole diaphragm. The scattering-contrast diaphragm defines a scattering-contrast aperture having a cross-dimension greater than the cross-dimension of the pinhole aperture. By way of example, if the patterned beam on the image plane has transverse dimensions of 1-mm square, then the pinhole aperture desirably has a diameter of 10 μm or less, and the scattering-contrast aperture has a cross dimension of approximately 200 μm. The scattering-contrast aperture removes charged particles that have been scattered outside the aperture portion of the pinhole aperture. This allows the characteristics of the charged particle beam, that has passed through the pinhole aperture, to be measured in a form that is more indicative of actual exposure conditions.

According to another aspect of the invention, CPB microlithography systems are provided. An embodiment of such a system comprises a reticle stage, an illumination-optical system, a projection-optical system, a substrate stage, a pinhole diaphragm, and a semiconductor amplifying CPB detector. The reticle stage is configured to hold a reticle that defines a pattern to be transferred to a lithographic substrate. The illumination-optical system is situated upstream of the reticle stage and is configured to illuminate the pattern with a charged-particle illumination beam, thereby forming a patterned beam propagating downstream of the reticle. The patterned beam carries an aerial image of the illuminated portion of the reticle. The projection-optical system is situated downstream of the reticle stage and is configured to direct the patterned beam onto the lithographic substrate and to resolve the aerial image on a sensitive surface of the substrate. The substrate stage is situated downstream of the projection-optical system and is configured to position and hold the lithographic substrate at an image plane for exposure by the patterned beam. The pinhole diaphragm is situated at the image plane and defines a pinhole aperture. The semiconductor amplifying CPB detector (e.g., PIN photodiode) is situated downstream of the pinhole diaphragm such that charged particles of the patterned beam passing through the pinhole aperture are incident on the CPB detector. The CPB detector is configured to amplify a current of the incident beam, thereby producing an amplified output current corresponding to a measurement of a distribution of charged-particle density of the incident beam.

The system also includes a deflector situated and configured (e.g., in the projection-optical system) to deflect the patterned beam over the pinhole aperture. Such deflection causes the patterned beam to be “scanned” over the pinhole aperture as the beam, downstream of the pinhole aperture, is incident on the CPB detector. Such scanning results in determinations of the distribution of charged-particle density being obtained at a high S/N ratio, which facilitates better regulation of the optical systems and the CPB source.

The system further can comprise a scattering-contrast diaphragm situated downstream of the pinhole diaphragm. The scattering-contrast diaphragm defines a scattering-contrast aperture having a cross-dimension greater than the cross-dimension of the pinhole aperture.

The system further can comprise at least one respective corrective optical element in each of the illumination-optical system and the projection-optical system. The corrective optical elements are configured to apply a correction to the illumination beam and patterned beam, respectively, in response to an output of the CPB detector. The system further can comprise a CPB source situated upstream of the illumination-optical system, wherein the CPB source is configured to apply a correction to the illumination beam in response to an output of the CPB detector. In any event, multiple corrective elements are desirable because they allow one or more of the optical systems to be adjusted as required. Here, “corrective optical elements” encompasses any of various optical elements configured to correct, for example, image magnification, image warp, image position, aberrations, etc.

The system further can comprise at least one corrective optical element in the illumination-optical system and a CPB source situated upstream of the illumination-optical system. In such a configuration the corrective optical element and the CPB source are configured to apply respective corrections to the illumination beam in response to an output of the CPB detector.

Another aspect of the invention is set forth in the context of a CPB microlithography method for exposing a pattern, defined on a segmented reticle, onto a sensitive substrate. In the CPB microlithography method an illumination beam is directed to a region of the reticle so as to illuminate the region, and a corresponding patterned beam propagates downstream from the illuminated region to a lithographic substrate. The subject method is for measuring a lateral distribution, produced by the system, of charged-particle density of the exposed pattern (which can include a full-open pattern) on a substrate plane. According to an embodiment of the method, at an image plane (usually the substrate plane) of the CPB microlithography system, the patterned beam is passed through a pinhole aperture situated on the image plane. The pinhole aperture has a cross-dimension and is situated such that at least a portion of a patterned beam can pass through the pinhole aperture. Using a semiconductor amplifying CPB detector situated downstream of the pinhole aperture, a current of the portion of the patterned beam that passes through the pinhole aperture and that is incident on the CPB detector is received and detected. The detected current is an amplified output current. The method further can include the step of passing the portion of the patterned beam, that has passed through the pinhole aperture, through a scattering-contrast aperture having a cross-dimension greater than the cross-dimension of the pinhole aperture, so as to block propagation to the CPB detector of charged particles that were scattered significantly during passage through the pinhole aperture.

The method further can comprise the step of scanning the patterned beam relative to the pinhole aperture while detecting a current of the portion of the patterned beam that passes through the pinhole aperture.

The method further can comprise the step of moving the pinhole aperture relative to the patterned beam while detecting a current of the portion of the patterned beam that passes through the pinhole aperture.

The method further can comprise the step of adjusting at least one of the CPB source, the illumination-optical system, and the projection-optical system based on the amplified output current.

The foregoing and additional features and advantages of the invention will be more readily apparent from the following detailed description, which proceeds with reference to the accompanying drawings.

### BRIEF DESCRIPTION OF THE DRAWINGS

FIG. 1 is an elevational schematic optical diagram showing a representative embodiment of a device for measuring the distribution of charged-particle density in a charged-particle-beam (CPB) microlithography apparatus.

FIG. 2 is an elevational schematic diagram of imaging relationships and control systems of a CPB microlithography apparatus with which the device shown in FIG. 1 is used.

FIG. 3 shows an exemplary profile of the distribution signal produced by the device of FIG. 1.

### DETAILED DESCRIPTION

The invention is described below in connection with a representative embodiment that is not intended to be limiting in any way. Although the embodiment is described as utilizing an electron beam as an exemplary charged particle beam, the general principles set forth herein are applicable with equal facility to the use of an alternative charged particle beam such as an ion beam.

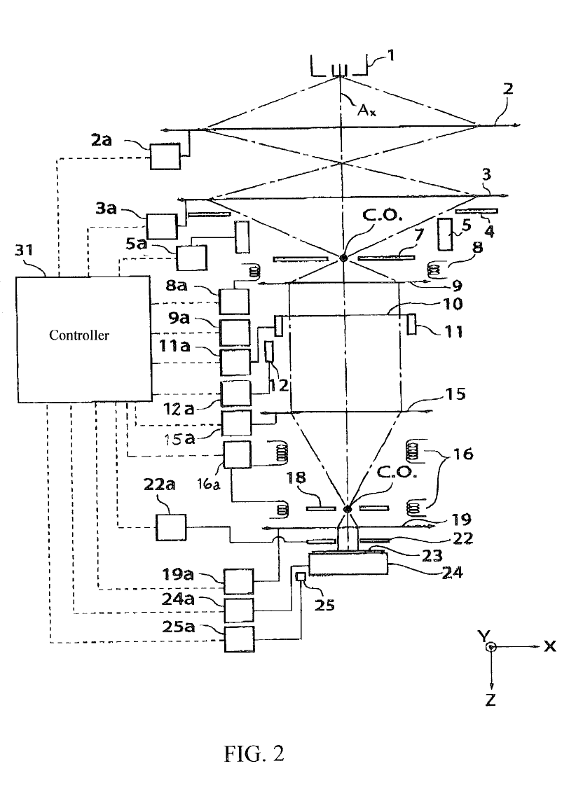

First, an overview of a charged-particle-beam (CPB) microlithography system utilizing a divided reticle is set forth, referring to FIG. 2, which depicts an overview of imaging and control relationships of the CPB optical system.

Situated at the extreme upstream end of the system is an electron gun 1 that emits an electron beam propagating in a downstream direction generally along an optical axis Ax. Downstream of the electron gun 1 are a first condenser lens 2 and a second condenser lens 3 collectively constituting a two-stage condenser-lens assembly. The condenser lenses 2, 3 converge the electron beam at a crossover C.O. situated on the optical axis Ax at a blanking diaphragm 7.

Downstream of the second condenser lens 3 is a “beam-shaping diaphragm” 4 comprising a plate defining an axial aperture (typically rectangular in profile) that trims and shapes the electron beam passing through the aperture. The aperture is sized and configured to trim the electron beam sufficiently to illuminate one exposure unit (e.g., a “subfield”) on the reticle 10. An image of the beam-shaping diaphragm 4 is formed on the reticle 10 by an illumination lens 9.

The electron-optical components situated between the electron gun 1 and the reticle 10 collectively constitute an “illumination-optical system” of the depicted microlithography system. The electron beam propagating through the illumination-optical system is termed an “illumination beam” because it illuminates a desired region of the reticle 10. As the illumination beam propagates through the illumination-optical system, the beam actually travels in a downstream direction through an axially aligned “beam tube” (not shown but well understood in the art) that can be evacuated to a desired vacuum level.

A blanking deflector 5 is situated downstream of the beam-shaping aperture 4. The blanking deflector 5 laterally deflects the illumination beam as required to cause the illumination beam to strike the aperture plate of the blanking diaphragm 7, thereby preventing the illumination beam from being incident on the reticle 10.

A subfield-selection deflector 8 is situated downstream of the blanking diaphragm 7. The subfield-selection deflector 8 laterally deflects the illumination beam as required to illuminate a desired exposure unit situated on the reticle within the optical field of the illumination optical system. Thus, exposure units of the reticle 10 are scanned sequentially by the illumination beam in a horizontal direction (X direction in the figure). The illumination lens 9, which forms the image of the beam-shaping diaphragm 4 on the reticle 10, is situated downstream of the subfield-selection deflector 8.

The reticle 10 typically defines many exposure units (e.g., tens of thousands of subfields). The exposure units collectively define the pattern for a layer to be formed at a single die (“chip”) on a lithographic substrate. The reticle 10 is mounted on a movable reticle stage 11. Using the reticle stage 11, by moving the reticle 10 in a direction (Y and/or X direction) perpendicular to the optical axis Ax, it is possible to illuminate the respective exposure units on the reticle 10 extending over a range that is wider than the optical field of the illumination-optical system. The position of the reticle stage 11 in the XY plane is determined using a “position detector” 12 that typically is configured as a laser interferometer. The laser interferometer is capable of measuring the position of the reticle stage 11 with extremely high accuracy in real time.

Situated downstream of the reticle 10 are first and second projection lenses 15, 19, respectively, and an imaging-position deflector 16. The illumination beam, by passage through an illuminated exposure unit of the reticle 10, becomes a “patterned beam” because the beam has acquired an aerial image of the illuminated subfield. The patterned beam is imaged at a specified location on a substrate 23 (e.g., “wafer”) by the projection lenses 15, 19 collectively functioning as a “projection-lens assembly.” To ensure imaging at the proper location, the imaging-position deflector 16 imparts the required lateral deflection of the patterned beam.

So as to be imprintable with the image carried by the patterned beam, the upstream-facing surface of the substrate 23 is coated with a suitable “resist” that is imprintably sensitive to exposure by the patterned beam. When forming the image on the substrate, the projection-lens assembly “reduces” (demagnifies) the aerial image. Thus, the image as formed on the substrate 23 is smaller (usually by a defined integer-ratio factor termed the “demagnification factor”) than the corresponding region illuminated on the reticle 10. By thus causing imprinting on the surface of the substrate 23, the apparatus of FIG. 2 achieves “transfer” of the pattern image from the reticle 10 to the substrate 23.

The components of the depicted electron-optical system situated between the reticle 10 and the substrate 23 collectively are termed the “projection-optical system.” The substrate 23 is mounted to a substrate stage 24 situated downstream of the projection-optical system. As the patterned beam propagates through the projection-optical system, the beam actually travels in a downstream direction through an axially aligned “beam tube” (not shown but well understood in the art) that can be evacuated to a desired vacuum level.

The projection-optical system forms a crossover C.O. of the patterned beam on the optical axis Ax at the back focal plane of the first projection lens 15. The position of the crossover C.O. on the optical axis Ax is a point at which the axial distance between the reticle 10 and substrate 23 is divided according to the demagnification ratio. Situated between the crossover C.O. (i.e., the rear focal plane) and the reticle 10 is a contrast-aperture diaphragm 18. The contrast-aperture diaphragm 18 comprises an aperture plate that defines an aperture centered on the axis Ax. With the contrast-aperture diaphragm 18, electrons of the patterned beam that were scattered during transmission through the reticle 10 are blocked so as not to reach the substrate 23.

A backscattered-electron (BSE) detector 22 is situated immediately upstream of the substrate 23. The BSE detector 22 is configured to detect and quantify electrons backscattered from certain marks situated on the upstream-facing surface of the substrate 23 or on an upstream-facing surface of the substrate stage 24. For example, a mark on the substrate 23 can be scanned by a beam that has passed through a corresponding mark pattern on the reticle 10. By detecting backscattered electrons from the mark at the substrate 23, it is possible to determine the relative positional relationship of the reticle 10 and the substrate 23.

The substrate 23 is mounted to the substrate stage 24 via a wafer chuck (not shown but well understood in the art), which presents the upstream-facing surface of the substrate 23 in an XY plane. The substrate stage 24 (with chuck and substrate 23) is movable in the X and Y directions. Thus, by simultaneously scanning the reticle stage 11 and the substrate stage 24 in mutually opposite directions, it is possible to transfer each exposure unit within the optical field of the illumination-optical system as well as each exposure unit outside the optical field to corresponding regions on the substrate 23. The substrate stage 24 also includes a “position detector” 25 configured similarly to the position detector 12 of the reticle stage 11.

Each of the lenses 2, 3, 9, 15, 19 and deflectors 5, 8, 16 is controlled by a controller 31 via a respective coil-power controller 2a, 3a, 9a, 15a, 19a and 5a, 8a, 16a. Similarly, the controller, via respective stage drivers 11a and 24a, controls operation of the reticle stage 11 and substrate stage 24. The position detectors 12, 25 produce and route respective stage-position signals to the controller 31 via respective interfaces 12a, 25a each including amplifiers, analog-to-digital (A/D) converters, and other circuitry for achieving such ends. In addition, the BSE detector 22 produces and routes signals to the controller 31 via a respective interface 22a.

From the respective data routed to it, the controller 31 ascertains, inter alia, any control errors of the respective stage positions as a subfield is being transferred. To correct such control errors, the imaging-position deflector 16 is energized appropriately to deflect the patterned beam. Thus, a reduced image of the illuminated exposure unit on the reticle 10 is transferred accurately to the desired target position on the substrate 23. This real-time correction is made as each respective image of an exposure unit is transferred to the substrate 23, and the images are positioned such that they are stitched together in a proper manner on the substrate 23.

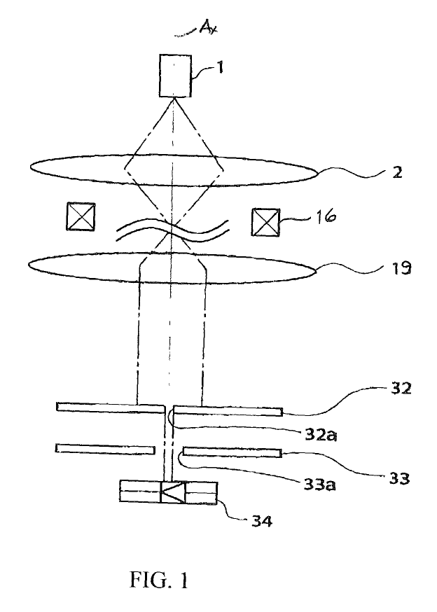

A representative embodiment of a device for measuring the distribution of charged-particle density in an illumination beam of a CPB microlithography system is shown in FIG. 1. In FIG. 1, components similar to respective components shown in FIG. 2 have the same respective reference numerals. Specifically, FIG. 1 depicts only the electron gun 1, the first condenser lens 2, the second projection lens 19, and the imaging-position deflector 16. The device of FIG. 1 also includes a plate-shaped “pinhole” diaphragm 32 defining a small pinhole aperture 32a. The pinhole diaphragm 32, desirably having a circular outer profile, is situated downstream of the imaging-position deflector 16 on the image plane of the projection-optical system. The pinhole diaphragm 32 desirably is positionable so that the pinhole aperture 32a can be situated on the optical axis Ax.

Charged particles (e.g., electrons) are irradiated from the electron gun 1 as an illumination beam. The illumination-optical system directs the illumination beam for irradiating a selected subfield on the reticle 10, thereby forming a corresponding patterned beam. The selected subfield can define any of various desired “patterns” (i.e., containing both beam-blocking or beam-scattering, as well as beam-transmissive portions) or can be “full-open” (i.e., lacking any beam-blocking or beam-scattering portions). The patterned beam is projected onto the surface of the pinhole aperture 32 by the projection-optical system (including the projection lens 15). Meanwhile, the patterned beam is deflected using the imaging-position deflector 16 so as to “scan” or sweep the patterned beam laterally relative to the aperture 32a on the pinhole diaphragm 32. Note that the obtained measurements of the distribution of charged-particle density are of the patterned beam that has passed through a subfield of the reticle 10 (see FIG. 2), wherein the image of the illuminated subfield is formed on the pinhole diaphragm 32.

As understood from the foregoing, the pinhole diaphragm 32 is situated at an imaging surface that is at the same “height” on the optical axis as the substrate 23 (FIG. 2). I.e., the pinhole diaphragm 32 is situated on the substrate plane. The cross-dimension (e.g., diameter) of the pinhole aperture 32a desirably is extremely small compared to the diameter of the patterned beam. This is because the spatial resolution of the distribution of charged-particle density is a function of the ratio of the respective diameters of the pinhole aperture 32a and of the patterned beam. For example, if the patterned beam on the image plane has transverse dimensions of 1 mm square, an aperture having a diameter (&Ovalsolid;) of 10 μm or less is desired. However, so long as the desired spatial resolution can be obtained, the cross-dimension of the pinhole aperture can be larger.

Downstream (e.g., 2 mm downstream) of the pinhole diaphragm 32 is a plate-shaped scattering-contrast diaphragm (beam-limiting diaphragm) 33 that desirably has a circular outer profile. The scattering-contrast diaphragm 33 defines a beam-limiting aperture 33a that desirably is centered on the axis Ax. Thus, the two apertures 32a, 33a are arranged concentrically. The scattering-contrast diaphragm 33 absorbs incident charged particles of the patterned beam that have been scattered during passage through the pinhole aperture 32a. Charged particles that were not scattered by the pinhole aperture 32a pass through the scattering-contrast aperture 33a. Since most of the scattered charged particles are absorbed by the scattering-contrast diaphragm 33, measurements of non-scattered charged particles propagating downstream of the scattering-contrast diaphragm are obtained at a higher resolution than would be obtainable if most of the scattered charged particles were not removed.

The cross dimension (e.g., diameter) of the scattering-contrast aperture 33a desirably is, according to the preceding example, approximately 200 μm. An aperture cross-dimension of this magnitude allows most of the scattered charged particles to be absorbed readily while allowing most of the non-scattered charged particles to pass through. Whether or not charged particles of the beam are scattered is a function of the acceleration energy of the charged particles and of the material and thickness of the material from which the pinhole diaphragm 32 is made. Thus, under certain conditions, it may be possible to omit the scattering-contrast diaphragm 33.

Charged particles that have passed through the apertures 32a, 33a are incident to a CPB-detecting device 34 situated downstream of the scattering-contrast diaphragm 33. In general, the CPB-detecting device 34 is a semiconductor CPB detector such as a PIN photodiode, which advantageously is extremely compact and rugged. The CPB-detecting device 34 produces an amplified output current. The amplification is due to the generation, by the device 34, of multiple electron-hole pairs by a single incident charged particle. By way of example, consider the CPB-detecting device 34 having a gain of 20,000. If 1 nA of charged particles is incident to the CPB-detecting device 34, the current produced by the CPB-detecting device (and available for measurement purposes) is 20 μA due to the gain provided by the CPB-detecting device. Such a gain provides an extremely high signal-to-noise (S/N) ratio.

The patterned beam does not pass through the pinhole aperture 32a during an actual lithographic exposure. Rather, the pinhole diaphragm 32, scattering-contrast diaphragm 33, and CPB-detecting device 34 are moved into position along the optical axis for making a measurement of beam-density distribution, and are displaced away from interfering with the charged particle beam during actual lithographic exposures. The measurement can be made as required (e.g., once per day of actual operation of the CPB microlithography system, or after any preventative maintenance, cleaning, or disassembly of the system). As noted above, when performing a measurement of beam-density distribution, the illumination beam can be directed through a patterned subfield or a “full-open” subfield.

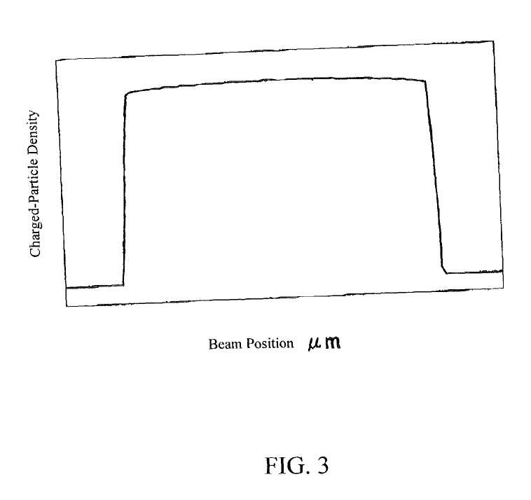

An exemplary distribution of charged-particle density as measured using the device described above is shown in FIG. 3. The abscissa is beam position, and the ordinate is charged-particle density at the beam position in question. Charged particles that have passed through the pinhole aperture 32a produce a nearly rectilinear density distribution, revealing a high S/N ratio.

Since the distribution of charged-particle density is measured with such a high S/N ratio, this distribution data can be used as feedback for adjusting the charged-particle source, the illumination-optical system, and the projection-optical system. To such end, the output from the CPB-detecting device can be routed to the controller 31 (FIG. 2) for processing, resulting in respective “adjustment commands” being produced and routed from the controller 31 to the charged-particle source, the illumination-optical system, and the projection-optical system. More specifically, for example, the adjustment commands are routed to any of various “corrective optical elements” in the illumination-optical system and projection-optical system. Exemplary corrective optical elements include any of various elements configured to correct, e.g., image magnification, image warp, image position, aberrations, etc. These adjustments made in response to the feedback data allow the distribution of charged-particle density to be optimized within the illuminated region at all times during exposure.

Whereas the invention has been described in connection with a representative embodiment, the invention is not limited to that embodiment. On the contrary, the invention is intended to encompass all modifications, alternatives, and equivalents as may be included within the spirit and scope of the invention, as defined by the appended claims.

What is claimed:

1. In a charged-particle-beam (CPB) microlithography system for exposing a pattern, defined on a segmented reticle, onto a sensitive substrate, a device for measuring a lateral distribution, produced by the system, of charged-particle density of the exposed pattern, which can include a full-open pattern, on a substrate plane, the device comprising:
a pinhole diaphragm, defining a pinhole aperture, situated on an image plane of the CPB microlithography system, the pinhole aperture having a cross-dimension and being situated such that at least a portion of a patterned beam, propagating downstream of a reticle plane of the CPB microlithography system, can pass through the pinhole aperture; and
a semiconductor amplifying CPB detector situated downstream of the pinhole aperture, the CPB detector being configured to receive the portion of the patterned beam passing through the pinhole aperture and that are incident on the CPB detector, to detect the incident charged particles, and to produce an amplified output current from the detected incident charged particles.

2. The device of claim 1, further comprising a scattering-contrast diaphragm situated downstream of the pinhole diaphragm, the scattering-contrast diaphragm defining a scattering-contrast aperture having a cross-dimension greater than the cross-dimension of the pinhole aperture.

3. The device of claim 2, wherein:
the patterned beam on the image plane has transverse dimensions of 1-mm square; and
the pinhole aperture has a diameter of 10 μm or less.

4. The device of claim 3, wherein the scattering-contrast aperture has a cross dimension of approximately 200 μm.

5. The device of claim 1, wherein:
the patterned beam on the image plane has transverse dimensions of 1-mm square; and
the pinhole aperture has a diameter of 10 μm or less.

6. The device of claim 1, wherein the CPB detector is a PIN photodiode.

7. A charged-particle-beam (CPB) microlithography system, comprising:
a reticle stage configured to hold a reticle that defines a pattern to be transferred to a lithographic substrate;
an illumination-optical system situated upstream of the reticle stage and configured to illuminate the pattern with a charged-particle illumination beam, thereby forming a patterned beam propagating downstream of the reticle, the patterned beam carrying an aerial image of the illuminated portion of the reticle;
a projection-optical system situated downstream of the reticle stage and configured to direct the patterned beam onto the lithographic substrate and to resolve the aerial image on a sensitive surface of the substrate;
a deflector situated and configured to deflect the patterned beam;
a substrate stage situated downstream of the projection-optical system and configured to position and hold the lithographic substrate at an image plane for exposure by the patterned beam;
a pinhole diaphragm situated at the image plane, the pinhole diaphragm defining a pinhole aperture over which the deflector deflects the patterned beam; and
a semiconductor amplifying CPB detector situated downstream of the pinhole diaphragm such that charged particles of the patterned beam passing through the pinhole aperture are incident on the CPB detector, the CPB detector being configured to amplify a current of the incident beam, thereby providing an amplified output current corresponding to a measurement of a distribution of charged-particle density of the incident beam.

8. The system of claim 7, further comprising a scattering-contrast diaphragm situated downstream of the pinhole diaphragm, the scattering-contrast diaphragm defining a scattering-contrast aperture having a cross-dimension greater than the cross-dimension of the pinhole aperture.

9. The system of claim 8, wherein:
the patterned beam on the image plane has transverse dimensions of 1-mm square; and
the pinhole aperture has a diameter of 10 μm or less.

10. The system of claim 9, wherein the scattering-contrast aperture has a cross dimension of approximately 200 μm.

11. The system of claim 7, wherein the deflector is located in the projection-optical system.

12. The system of claim 7, further comprising at least one respective corrective optical element in each of the illumination-optical system and the projection-optical system, the corrective optical elements being configured to apply a correction to the illumination beam and patterned beam, respectively, in response to an output of the CPB detector.

13. The system of claim 12, further comprising a CPB source situated upstream of the illumination-optical system, the CPB source being configured to apply a correction to the illumination beam in response to an output of the CPB detector.

14. The system of claim 7, further comprising:
at least one corrective optical element in the illumination-optical system; and
a CPB source situated upstream of the illumination-optical system, the corrective optical element and the CPB source being configured to apply respective corrections to the illumination beam in response to an output of the CPB detector.

15. The system of claim 7, wherein the CPB detector is a PIN photodiode.

16. In a charged-particle-beam (CPB) microlithography method for exposing a pattern, defined on a segmented reticle, onto a sensitive substrate, wherein an illumination beam is directed to a region of the reticle so as to illuminate the region, and a corresponding patterned beam propagates downstream from the illuminated region to a lithographic substrate, a method for measuring a lateral distribution, produced by the system, of charged-particle density of the exposed pattern, which can include a full-open pattern, on a substrate plane, the method comprising:
at an image plane of the CPB microlithography system, passing the patterned beam through a pinhole aperture situated on an image plane of the CPB microlithography system, the pinhole aperture having a cross-dimension and being situated such that at least a portion of a patterned beam can pass through the pinhole aperture; and
using a semiconductor amplifying CPB detector situated downstream of the pinhole aperture, producing an amplified output current by detecting the portion of the patterned beam that passes through the pinhole aperture and that is incident on the CPB detector.

17. The method of claim 16, further comprising the step of passing the portion of the patterned beam, that has passed through the pinhole aperture, through a scattering-contrast aperture having a cross-dimension greater than the cross-dimension of the pinhole aperture, so as to block propagation to the CPB detector of charged particles that were scattered significantly during passage through the pinhole aperture.

18. The method of claim 17, wherein:
the patterned beam incident to the pinhole aperture has transverse dimensions of 1-mm square; and
the pinhole aperture has a diameter of 10 μm or less.

19. The method of claim 18, wherein the scattering-contrast aperture has a cross dimension of approximately 200 μm.

20. The method of claim 16, further comprising the step of scanning the patterned beam relative to the pinhole aperture while detecting a current of the portion of the patterned beam that passes through the pinhole aperture.

21. The method of claim 16, further comprising the step of moving the pinhole aperture relative to the patterned beam while producing the amplified output current of the portion of the patterned beam that passes through the pinhole aperture.

22. The method of claim 16, wherein the illumination beam is produced by a CPB source and passes through an illumination-optical system to the reticle, and the patterned beam passes through a projection-optical system from the reticle to the pinhole aperture, the method further comprising the step of adjusting at least one of the CPB source, the illumination-optical system, and the projection-optical system based on the amplified output current.
